(19) United States
(12) Patent Application Publication
(10) Pub. No.: US 2026/0099100 A1
(43) Pub. Date: Apr. 9, 2026

(54) OPTICAL SUBASSEMBLY

(71) Applicant: Carl Zeiss SMT GmbH, Oberkochen (DE)

(72) Inventor: Ralf AMELING, Aalen (DE)

(21) Appl. No.: 19/379,235

(22) Filed: Nov. 4, 2025

Related U.S. Application Data
(63) Continuation of application No. PCT/EP2024/062249, filed on May 3, 2024.

(30) Foreign Application Priority Data
May 10, 2023 (DE) 10 2023 204 312.2

(51) Int. Cl. G03F 7/00; G02B 26/08

(52) U.S. Cl. CPC G03F 7/70833; G02B 26/0858; G03F 7/70266; G03F 7/70316

(57) ABSTRACT

An optical assembly for an illumination optics unit or a projection optics unit of a projection exposure apparatus comprises at least one optical component, a load-bearing structure, and a bearing device. The at least one optical component is mounted on the load-bearing structure via the bearing device. The bearing device comprises one or more active elements for the at least partial compensation of deformations of the load-bearing structure.

### CROSS-REFERENCE TO RELATED APPLICATIONS

The present application is a continuation of, and claims benefit under 35 USC 120 to, international application No. PCT/EP2024/062249, filed May 3, 2024, which claims benefit under 35 USC 119 of German Application No. 10 2023 204 312.2, filed May 10, 2023. The entire disclosure of each of these applications is incorporated by reference herein.

### FIELD

The disclosure relates to an optical assembly for an illumination optics unit or a projection optics unit of a projection exposure apparatus. For example, the optical assembly may be a constituent part of a facet mirror, such as a field facet mirror or a pupil facet mirror in an illumination optics unit of a projection exposure apparatus. The illumination optics unit in turn may be a constituent part of an illumination system and/or an optical system in a projection exposure apparatus. In this case, the optical system also may comprise a projection optics unit in addition to the illumination optics unit. The optical assembly may be a constituent part of the projection optics unit. A method for producing microstructured or nanostructured components and the corresponding components can be improved using the optical assembly.

### BACKGROUND

It is known to use micromirror arrays in illumination optics units for projection exposure apparatuses.

### SUMMARY

An issue that can arise with the use of displaceable mirrors is that of ensuring the precise and stable positioning thereof, even for the case of a high thermal load.

There is a general desire to improve optical components and assemblies, such as with micromirrors, for example with regard to the bearing of the optical components, for example mirror elements.

An aspect of the disclosure includes providing a bearing device for mounting an optical component, such as in the form of a mirror element, having one or more active elements for the at least partial compensation of deformations of a load-bearing structure.

As a result, the precision of the arrangement of the optical component can be improved, even for the case of a high thermal load.

For example, the optical component may be a mirror element, such as a micromirror.

In this context, a micromirror should be understood to mean in particular a mirror with a reflection surface of no more than 10 mm², such as no more than 3 mm², for example no more than 1 mm².

An active element should be understood to mean, in particular, a mechanical structure whose properties can be changed in a controlled manner.

An active element may for example have an adjustable length and/or an adjustable stiffness and/or an adjustable orientation.

The load-bearing structure may be partially composed of metal or ceramic, such as predominantly composed of metal or ceramic, for example completely composed of metal or ceramic.

The load-bearing structure may comprise further functional elements, such as electronic components and/or constituent parts of a cooling device. For details, reference can be made to DE 10 2022 209 935.4.

Heat can be dissipated from the optical components via the load-bearing structure.

In accordance with an aspect, the optical assembly comprises a multiplicity of optical components, especially in the form of mirror elements. These may jointly form a group, such as a mirror group.

In this context, a grouping should be understood to mean, in particular, that a plurality of the optical components of the same group interact functionally. For example, the reflection surface of a macroscopic mirror may be formed by a multiplicity of micromirrors.

The mirror elements may be micromirrors, for example.

According to an aspect, the optical components are in the form of microelectromechanical systems (MEMS). For example they may be in the form of microoptoelectromechanical systems (MOEMS).

As a result, the production of the optical components may be facilitated. The optical components may be produced from silicon or a silicon compound for example.

According to a further aspect, the optical components are pivotable via an actuator device. The actuator device may comprise actuator elements that are in the form of MEMS.

For example, the optical components may have one or two pivoting degrees of freedom. They may also have one or two or three translational degrees of freedom. It is also conceivable to design the optical components to be deformable.

According to a further aspect, the bearing device comprises a base plate that is arranged between the load-bearing structure and the optical components.

One or more layers with electrical connections may be provided in the base plate, which is also referred to as a plate-shaped substrate, or on the base plate.

The base plate or the plate-shaped substrate may be produced from, for example consist of, a semiconductor material, such as silicon, or a semiconductor compound, such as a silicon compound.

According to a further aspect, at least a subset of the active elements of the bearing device is arranged on the sides of the base plate opposite the optical components.

For example, this may apply to all active elements of the bearing device.

In this case, the active elements may be arranged between the load-bearing structure and the base plate for example.

For example, the active elements of the bearing device may serve to compensate for a deformation of the load-bearing structure, such as on account of a heat input, at least part and for example to the greatest possible extent.

For example, the active elements may be used to decouple the base plate from the load-bearing structure. A deformation of the base plate that might otherwise result on account of a deformation of the load-bearing structure can be reduced, for example avoided, with the aid of the active elements.

For example, the active elements may be designed in such a way that they can generate a force perpendicular to the interface. What can be achieved as a result is that a deformation of the base plate is reduced, for example avoided, in the event of a deformation of the load-bearing structure.

According to an aspect, at least a subset of the active elements, for example all of the active elements, is or are in the form of piezo-actuators or capacitive actuators or comprises or comprise piezo-actuators or capacitive actuators.

For example, the active elements may comprise or form z-actuators. For example, they may generate a force that acts substantially along a normal with respect to the upper side of the load-bearing structure and/or with respect to the lower side of the base plate.

According to a further aspect, at least a subset of the active elements comprises a plurality of piezo actuators. For example, this may apply to all of the active elements.

For example, a single active element may be realized by two piezo stacks that are connected to each other. This renders a link, for example of the base plate, relative to the load-bearing structure possible.

For example, a single active element may be realized by three piezo stacks that are connected to one another. This renders tilts with two tilt degrees of freedom possible.

For example, a single active element may also be realized by four piezo stacks that are connected to one another, such as four symmetrically arranged piezo stacks, for example as are used in piezo stepper motors, for example. What can be achieved as a result is that a single active element may provide even better compensation of deformations at the interface between the load-bearing structure and the base plate. In addition to the application of a z-force, it is also possible to compensate for a different orientation of the upper side of the load-bearing structure with respect to the lower side of the base plate.

According to a further aspect, at least a subset of the active elements is connected to the base plate by way of decoupling elements. For example, this may apply to all of the active elements.

The decoupling elements may be embodied in such a way that they provide decoupling in one direction or in one plane, i.e. in two linearly independent directions.

The decoupling elements may be passive elements. For example, they may be embodied in the form of a spring structure.

The decoupling elements may be integrated into and/or attached to the active elements.

According to a further aspect, each of the optical components is assigned in each case one or more active elements.

This can help allow for relatively flexible compensation of deformations of the load-bearing structure and/or of the base plate.

The active elements that are assigned to specific individual optical components may also be arranged on the same side of the base plate as the respective optical components. For example, they may also be provided in addition to active elements on the side of the base plate opposite the optical components.

According to a further aspect, the active elements are each assigned to a group of optical components.

This may apply to all of the active elements or a subset thereof.

In this case, the arrangement of the active elements may be independent of the arrangement of the optical components. For example, the density of the compensation elements may vary over the extent of the optical assembly, for example over the extent of the load-bearing structure and/or over the extent of the base plate. For example, the density of the active elements may be greater at those locations for example at which larger deformations are expected. For example, the density of the compensation elements may be adapted to the thermal load to be expected. For example, the density may lie in the range from one active element per 100 micromirrors through 1 active element per micromirror to 4 or more active elements per micromirror.

According to a further aspect, the active elements may form constituent parts of a feedback control system.

This can help allow more precise compensation of deformations.

The feedback control system may also comprise one or more sensors. One or more state variables of the optical components, such as the mirrors, and/or of the base plate and/or of the load-bearing structure may be acquired with the aid of the sensors. For example, the state variables might be a selection from temperature, distances, expansions and mechanical stresses.

The sensors may be arranged at different locations in the optical assembly.

According to a further aspect, the active elements may form constituent parts of a pure feed-forward system.

In this case, the forces for compensating the deformations may be ascertained with the aid of a model. With the aid of such a model, the thermal deformations to be expected may be determined on the basis of the incident radiant power, such as on the basis of the radiant power distribution.

Calculations, simulations and/or calibration measurements may be included in the model. According to further aspects, the optical assembly may form a module or a facet mirror, such as a field facet mirror or a pupil facet mirror, in an illumination optics unit of a projection exposure apparatus.

The optical assembly overall may also form a facet mirror, such as a field facet mirror or a pupil facet mirror, in an illumination optics unit of a projection exposure apparatus.

Further subjects of the disclosure include an illumination optics unit having an optical assembly according to the preceding description and an illumination system having such an illumination optics unit and a radiation source for generating illumination radiation, such as in the EUV range. Further subjects of the disclosure moreover are a projection optics unit having an optical assembly according to the preceding description, an optical system having an illumination optics unit and/or a projection optics unit according to the preceding description, and a projection exposure apparatus having such an illumination optics unit and/or such a projection optics unit.

The optical assembly according to the preceding description can lead to an improvement in a method for producing microstructured or nanostructured components and in such components produced according to the method.

All of these subjects are encompassed by the disclosure.

### BRIEF DESCRIPTION OF THE DRAWINGS

Further details and features of the disclosure that result therefrom are described with reference to the figures on the basis of exemplary embodiments. In the figures:

FIG. 1 schematically shows certain constituent parts of a projection exposure apparatus in a meridional section;

FIGS. 2 and 3 schematically show a view of a displaceable mirror element which forms a constituent part of a mirror array of a facet mirror for an illumination optics unit in a projection exposure apparatus;

FIG. 4 schematically shows a cross section through a portion of a micromirror array;

FIG. 5 schematically shows a view of an arrangement of a micromirror array on a load-bearing structure, with an interposer arranged between the micromirror array and the load-bearing structure;

FIG. 6 schematically shows a cross section through a micromirror array, in which a bearing device for mounting the individual mirrors comprises a base plate that is arranged on a load-bearing structure via active elements;

FIG. 7 schematically shows a detail view of an active element in the form of a piezo stack for mounting the base plate on the load-bearing structure;

FIG. 8 schematically shows a view according to FIG. 7, with a passive decoupling structure being arranged on the piezo stack;

FIG. 9 schematically shows a view of an active element that is formed from a plurality of piezo actuators; and

FIG. 10 schematically shows a view of the active element according to FIG. 9 in the deflected state.

### DETAILED DESCRIPTION

The general structure of a projection exposure apparatus 1 and the constituent parts thereof will be described. For details in this regard, reference should be made to WO 2010/049076 A2, which is hereby fully incorporated in the present application as part thereof. The description of the general structure of the projection exposure apparatus 1 should only be understood to be exemplary. It serves to explain a possible application of the subject matter of the present disclosure. The subject matter of the present disclosure may also be used in other optical systems, such as in alternative variants of projection exposure apparatuses. For example, the concept described hereinafter is not restricted to the structure of the projection exposure apparatus 1, depicted in exemplary fashion, or the constituent parts thereof. For example, its application is not restricted to the specific MEMS design presented in exemplary fashion in this context.

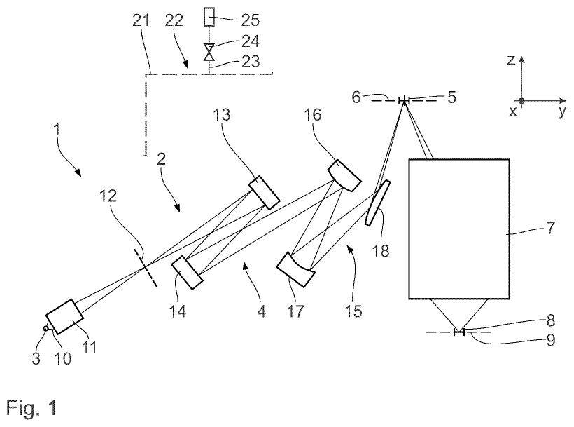

FIG. 1 schematically shows a microlithographic projection exposure apparatus 1 in a meridional section. An illumination system 2 of the projection exposure apparatus 1 has, besides a radiation source 3, an illumination optics unit 4 for the exposure of an object field 5 in an object plane 6. The object field 5 may have a rectangular or arcuate design with an x/y-aspect ratio of 13/1, for example. In this case, a reflective reticle (not depicted in FIG. 1) arranged in the object field 5 is exposed, the reticle bearing a structure to be projected by the projection exposure apparatus 1 for the production of microstructured or nanostructured semiconductor components. A projection optics unit 7 serves for imaging the object field 5 into an image field 8 in an image plane 9. The structure on the reticle is imaged onto a light-sensitive layer of a wafer, which is not depicted in the drawing and is arranged in the region of the image field 8 in the image plane 9.

The reticle, which is held by a reticle holder (not depicted here), and the wafer, which is held by a wafer holder (not depicted here), are scanned synchronously in the y-direction during the operation of the projection exposure apparatus 1. Depending on the imaging scale of the projection optics unit 7, it is also possible for the reticle to be scanned in the opposite direction relative to the wafer.

The radiation source 3 is an EUV radiation source with emitted used radiation in the range of between 5 nm and 30 nm. This may be a plasma source, for example a GDPP (Gas Discharge Produced Plasma) source or an LPP (Laser Produced Plasma) source. Other EUV radiation sources, for example those based on a synchrotron or on a free electron laser (FEL), are also possible.

EUV radiation 10 emerging from the radiation source 3 is focused by a collector 11. A corresponding collector is known for example from EP 1 225 481 A2. Downstream of the collector 11, the EUV radiation 10 propagates through an intermediate focal plane 12 before being incident on a field facet mirror 13. The field facet mirror 13 is arranged in a plane of the illumination optics unit 4 optically conjugate to the object plane 6. The field facet mirror 13 may be arranged at a distance from a plane that is conjugate to the object plane 6. In this case, it is generally referred to as a first facet mirror.

The EUV radiation 10 is also referred to hereinafter as used radiation, illumination radiation or imaging light.

Downstream of the field facet mirror 13, the EUV radiation 10 is reflected off a pupil facet mirror 14. The pupil facet mirror 14 is located either in the entrance pupil plane of the projection optics unit 7 or in a plane optically conjugate thereto. It may also be arranged at a distance from such a plane.

The field facet mirror 13 and the pupil facet mirror 14 are constructed from a multiplicity of individual mirrors, which will still be described in detail below. In this case, the subdivision of the field facet mirror 13 into individual mirrors can be such that each of the field facets illuminating the entire object field 5 by themselves is represented by exactly one of the individual mirrors. Alternatively, it is possible to construct at least some or all of the field facets using a plurality of such individual mirrors. The same correspondingly applies to the configuration of the pupil facets of the pupil facet mirror 14, which are each assigned to the field facets and each of which may be formed by a single individual mirror or by a plurality of such individual mirrors.

The EUV radiation 10 is incident on both facet mirrors 13, 14 at a defined angle of incidence. For example, the two facet mirrors are exposed to EUV radiation 10 in the range associated with normal incidence operation, i.e. at an angle of incidence that is less than or equal to 25° in relation to the mirror normal. Exposure to grazing incidence is also possible. The pupil facet mirror 14 is arranged in a plane of the illumination optics unit 4 that constitutes a pupil plane of the projection optics unit 7 or is optically conjugate to a pupil plane of the projection optics unit 7. With the aid of the pupil facet mirror 14 and—optionally—an imaging optical assembly in the form of a transfer optics unit 15 which has mirrors 16, 17 and 18 designated in the order of the beam path for the EUV radiation 10, the field facets of the field facet mirror 13 are imaged into the object field 5 in a manner superimposed on one another. The last mirror 18 of the transfer optics unit 15 is a mirror for grazing incidence (“grazing incidence mirror”). The transfer optics unit 15 together with the pupil facet mirror 14 is also referred to as a sequential optics unit for transferring the EUV radiation 10 from the field facet mirror 13 toward the object field 5. The illumination light 10 is guided from the radiation source 3 toward the object field 5 via a plurality of illumination channels. Each of these illumination channels is assigned a field facet of the field facet mirror 13 and a pupil facet of the pupil facet mirror 14, the pupil facet being disposed downstream of the field facet. The individual mirrors of the field facet mirror 13 and of the pupil facet mirror 14 may be tiltable by an actuator system, and so a change in the assignment of the pupil facets to the field facets and correspondingly a modified configuration of the illumination channels may be achieved. This results in different illumination settings, which differ in the distribution of the illumination angles of the illumination light 10 over the object field 5.

In order to facilitate the explanation of positional relationships, a global Cartesian xyz-coordinate system, inter alia, is used hereinafter. The x-axis runs perpendicular to the plane of the drawing toward the observer in FIG. 1. The y-axis in FIG. 1 runs toward the right. The z-axis in FIG. 1 runs upward.

Different illumination settings may be achieved by tilting the individual mirrors of the field facet mirror 13 and correspondingly modifying the assignment of the individual mirrors of the field facet mirror 13 to the individual mirrors of the pupil facet mirror 14. Depending on the tilt of the individual mirrors of the field facet mirror 13, the individual mirrors of the pupil facet mirror 14 that are newly assigned to the individual mirrors are updated by tilting such that imaging the field facets of the field facet mirror 13 into the object field 5 is once again ensured.

Further aspects of the illumination optics unit 4 are described below.

The one field facet mirror 13 in the form of a multi-or micro-mirror array (MMA) forms an example of an optical assembly for guiding the used radiation 10, i.e. the EUV radiation beam. The field facet mirror 13 is in the form of a microelectromechanical system (MEMS). It comprises a multiplicity of individual mirrors 20 that are arranged in a mirror array 19 in rows and columns, like in a matrix. The mirror arrays 19 have a modular embodiment. They may be arranged on a load-bearing structure that is in the form of a base plate. Here, it is possible to arrange substantially any number of the mirror arrays 19 next to one another. Consequently, the overall reflection surface which is formed by the totality of all mirror arrays 19, such as by the individual mirrors 20 thereof, is extendable as desired. For example, the mirror arrays are embodied in such a way that they enable a substantially gap-free tessellation of a plane. The ratio of the sum of the reflection surfaces 26 of the individual mirrors 20 to the overall area that is covered by mirror arrays 19 is also referred to as integration density. For example, this integration density is at least 0.5, such as at least 0.6, for example at least 0.7, for example at least 0.8, for example at least 0.9.

The mirror arrays 19 may be fixed to a base plate, such as via fixing elements. For details, reference is made to WO 2012/130768 A2, for example.

The individual mirrors 20 are designed to be tiltable by way of an actuator. For details, reference is made to WO 2012/130 768 A2, for example. Overall, the field facet mirror 13 contains approximately 100 000 of the individual mirrors 20. The field facet mirror 13 may also have a different number of individual mirrors 20 depending on the size of the individual mirrors 20. The number of individual mirrors 20 of the field facet mirror 13 is such as at least 1000, for example at least 5,000, for example at least 10,000. It may be up to 100,000, such as up to 300,000, for example up to 500,000, for example up to 1,000,000.

A spectral filter may be arranged upstream of the field facet mirror 13 and separates the used radiation 10 from other wavelength components of the emission of the radiation source 3 that are not usable for the projection exposure. The spectral filter is not depicted here.

The entire individual mirror array of the facet mirror 13 has, for example, a diameter of 500 mm and is designed to be closely packed with the individual mirrors 20. Insofar as a field facet is realized by exactly one individual mirror in each case, the individual mirrors 20 represent the shape of the object field 5, apart from a scaling factor. The facet mirror 13 may be formed by 500 individual mirrors 20 which each represent a field facet and have a dimension of approximately 5 mm in the y-direction and 100 mm in the x-direction. As an alternative to the realization of each field facet by exactly one individual mirror 20, each of the field facets may be approximated by groups of smaller individual mirrors 20, for example micromirrors. A field facet having dimensions of 5 mm in the y-direction and of 100 mm in the x-direction may be constructed e.g. using a 1×20 array of individual mirrors 20 with dimensions of 5 mm×5 mm, through to a 10×200 array of individual mirrors 20 with dimensions of 0.5 mm×0.5 mm.

The tilt angles of the individual mirrors 20 are adjusted for the purpose of changing the illumination settings. For example, the tilt angles have a displacement range of ±50 mrad, such as ±100 mrad, for example ±200 mrad. An accuracy of better than 0.2 mrad, such as better than 0.1 mrad, is achieved within the scope of setting the tilt position of the individual mirrors 20.

The individual mirrors 20 of the field facet mirror 13 and of the pupil facet mirror 14 in the embodiment of the illumination optics unit 4 according to FIG. 1 bear multilayer coatings for the purpose of optimizing their reflectivity at the wavelength of the used radiation 10. For details, reference is made to DE 10 2013 206 529 A1, which is hereby fully incorporated into the present application.

The individual mirrors 20 of the illumination optics unit 4 are accommodated in an evacuable chamber 21, a boundary wall 22 of which is indicated in FIG. 1. The chamber 21 communicates with a vacuum pump 25 via a fluid line 23, in which a shut-off valve 24 is accommodated. The operating pressure in the evacuable chamber 21 is a few pascals.

Together with the evacuable chamber 21, the mirror comprising the plurality of individual mirrors 20 forms an optical assembly for guiding and/or shaping a beam of the EUV radiation 10.

Each of the individual mirrors 20 may have a reflection surface 26 with dimensions of 0.1 mm×0.1 mm, 0.5 mm×0.5 mm, 0.6 mm×0.6 mm, or else of up to 5 mm×5 mm or larger. The reflection surface 26 may also have smaller dimensions. For example, it has side lengths in the μm range or low mm range. The individual mirrors 20 are therefore also referred to as micromirrors.

The reflection surface 26 is part of a mirror body 27 of the individual mirror 20. The mirror body 27 carries the multilayer coating. The mirror body 27 may for example be produced from, such as consist of, a semiconductor material, for example silicon, or a semiconductor compound, for example a silicon compound.

For the lithographic production of a microstructured or nanostructured component, for example a semiconductor component, e.g. a microchip, at least one part of the reticle is imaged onto a region of a light-sensitive layer on the wafer with the aid of the projection exposure apparatus 1. Depending on the embodiment of the projection exposure apparatus 1 as a scanner or as a stepper, the reticle and the wafer are moved in the y-direction in a manner synchronized in time, continuously in scanner operation or step by step in stepper operation.

Further details and aspects of the mirror array 19, for example of the optical components which comprise the individual mirrors 20, are described below.

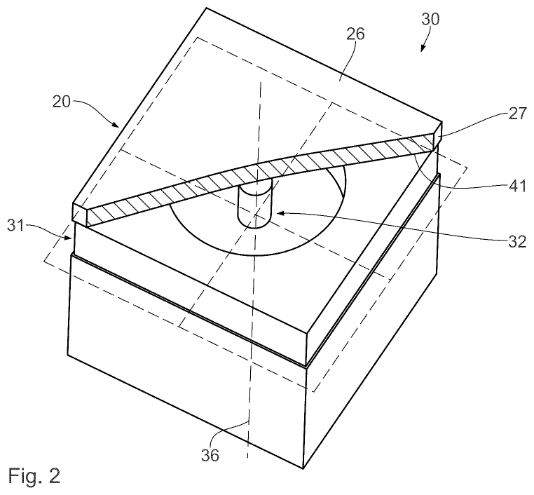

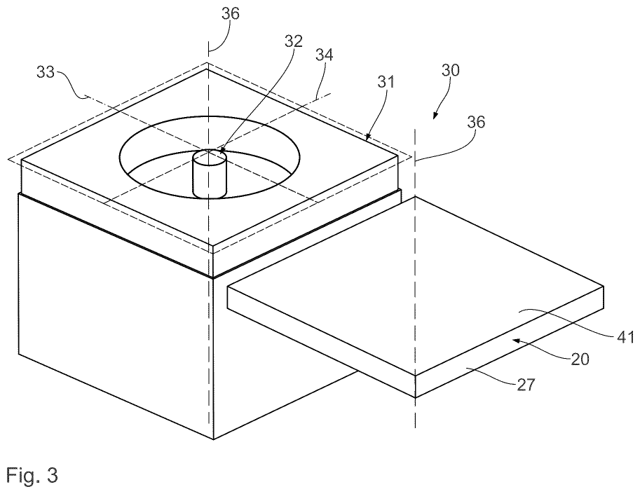

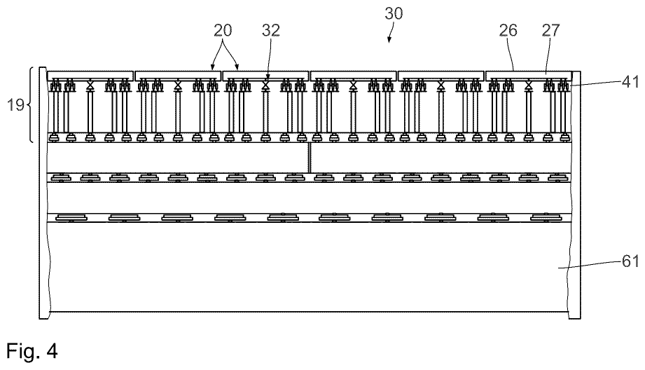

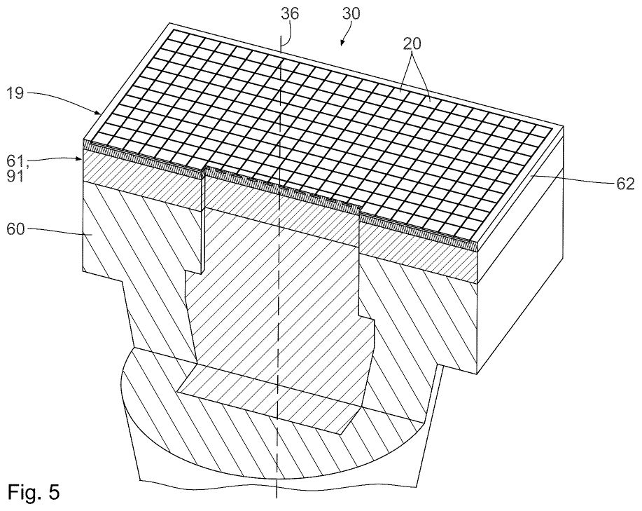

Initially, a first variant of an optical component 30 comprising an individual mirror 20 and for example the displacement device 31 for displacing, for example for pivoting, the individual mirror 20 is described in exemplary fashion with reference to FIGS. 2 and 3. These details should be understood to be exemplary and, for example, non-restrictive. Alternative embodiments of the component 30 are known and likewise possible.

The illustration according to FIG. 3 corresponds to that according to FIG. 2, with the mirror body 27 of the individual mirror 20 being folded away to the side in FIG. 3. As a result, the structures of the displacement device 31 and of the sensor device 41 are better visible.

The optical component comprises the individual mirror 20 which, for example, is in the form of a micromirror. The individual mirror 20 comprises the mirror body 27 described above, on the front side of which the reflection surface 26 is formed. For example, the reflection surface 26 is formed by a multilayer structure. For example, the radiation of the illumination radiation 10, for example of the EUV radiation, is reflected thereby.

The reflection surface 26 is square according to the variant depicted in the figures; however, it has been drawn in partly sectioned fashion in order also to show the actuator system. It generally has a rectangular embodiment. It may also have a triangular or hexagonal embodiment. For example, it has a tile-like embodiment such that a gap-free tessellation of a plane by way of the individual mirrors 20 is possible.

The individual mirror 20 is mounted via a joint 32. For example, it is mounted in such a way that it has two tilting degrees of freedom. For example, the joint 32 allows the individual mirror 20 to be tilted about two tilt axes 33, 34. The tilt axes 33, 34 are perpendicular to one another. They intersect at a central point of intersection, which is referred to as the effective pivot point.

To the extent that the individual mirror 20 is in a non-pivoted neutral position, the effective pivot point lies on a surface normal 36 which runs through a central point, for example the geometric centroid of the reflection surface 26.

To the extent that nothing else is specified, the direction of the surface normal 36 hereinafter is always understood to mean the direction of same in the non-tilted neutral position of the individual mirror 20.

Details of the displacement device 31 are known from the prior art.

Further details regarding the bearing of the individual mirrors 20, for example in the mirror array 19, are described below.

The individual mirrors 20 may be arranged on the plate 62 in groupwise fashion for example.

For example, the individual mirrors 20 are tiltable about two axes in the mirror plane. The bearing of the individual mirrors 20 also serves, inter alia, to dissipate a thermal load arising due to the EUV radiation.

To attain a fill factor of the individual mirrors 20 that is as high as possible, it is possible to arrange the entire actuator system, sensor system and further mechanical elements below the mirror surface (shadow casting principle). A layer-like structure of the elements is generally chosen in order to be able to realize the actuator, sensor and mechanical elements as MEMS.

To control the actuators to displace the individual mirrors 20 and read out the sensors to acquire the positioning of the individual mirrors 20, it is desirable if individual electronic elements, for example ASICs, are assigned to a group of a plurality of individual mirrors 20. It is also desirable to design a cooling device such that an entire group of individual mirrors 20 is cooled at the same time by a joint cooling means. To this end, it is desirable to combine the individual mirrors 20 into groups and, for example, arrange the mirror groups on a joint load-bearing structure 60. The cooling device and electronic components for the respective mirror group may be integrated into the load-bearing structure 60.

The individual mirrors 20 may be realized with MEMS processes, like the assigned actuator, sensor and mechanism elements. For example, they may be produced from, for example consist of, a semiconductor material, for example silicon, or a semiconductor compound, for example a silicon compound.

The different elements and/or constituent parts of the load-bearing structure 60 are usually not made of silicon, but for example made of copper or other metals or made of alloys or else made of ceramic.

There is thus an interface 91 between elements made of a semiconductor compound and elements made of another material, for example a metal or a ceramic. In the preceding examples, the interface 91 is formed by the decoupling device 61 (interposer). For example, the interface 91 extends between the load-bearing structure 60 and the plate 62, for example between the load-bearing structure 60 and the elements in the form of MEMS. It is therefore also referred to as a MEMS/load-bearing structure interface.

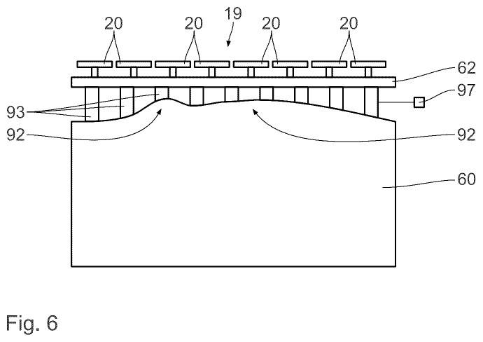

All of the heat absorbed by the individual mirrors 20 and other components on the front side of the plate 62 is dissipated through the interface 91 and supplied to the cooling system. Further elements of the load-bearing structure 60 are situated between the interface 91 and the cooling device. This may result in a thermal resistance between the interface 91 and the cooling device. This may lead to components located on the interface 91 also heating up. This may give rise to thermal deformations 92 of individual regions and/or constituent parts of the load-bearing structure 60. Deformations 92 are illustrated in exaggerated fashion in FIG. 6.

The elements adjacent to the interface 91 may be made of different materials, as described above. For example, they may have different coefficients of thermal expansion. The deformations 92 may arise in the region of the interface 91 as a result. If no suitable compensation is undertaken, the deformations 92 may lead to an undesired tilting of the individual mirrors 20 and of the associated actuator, sensor and mechanical elements. To the extent that the individual mirror 20 is tilted together with an associated sensor element for the purpose detecting the tilting thereof on account of a deformation 92, this tilting cannot be detected by the respective sensor element itself. This may give rise to tilt angle errors in the individual mirrors 20.

The distribution of the incident EUV radiation and for example of the absorbed EUV radiation 10 may vary both in time and in space. As a result of a variation of the incident radiation 10 over time, the tilt angle errors change constantly during the operation of the projection exposure apparatus 1. As a result of a variation of the incident radiation, for example of the radiation intensity, in space, individual local regions may have a relatively high thermal load and hence have locally pronounced thermal deformations 92, for example in the form of local bulges. Relatively large tilt angle errors may be caused as a result.

Active elements 93 may be provided in the region of the interface 91 for the purpose of compensating the deformations 92. The active elements 93 are illustrated purely schematically in FIG. 6.

Together with the plate 62, the active elements 93 form constituent parts of a bearing device for mounting the individual mirrors 20, for example for mounting the mirror array 19.

The active elements 93 are also referred to as compensation elements. They can generate a force perpendicular to the surface of the interface 91. What can be achieved as a result is that the plate 62 remains undeformed even in the case of deformations 92 in the load-bearing structure 60 or is at least deformed to a significantly lesser extent, such as at least 10% less, for example 30% less, for example 50% less, or deformed at least 90% less or deformed at least 99% less.

For example, the active elements 93 may be realized by piezo actuators or capacitive actuators. In this context, an active element 93 may be assigned to each individual mirror 20. The arrangement of the active elements 93 may also be independent of the arrangement of the individual mirrors 20. For example, the density of the active elements 93 may be greater at specific locations at which greater deformations 92 are expected, for example in a central region of a mirror group, for example of the mirror array 19. This makes it possible to apply greater forces at these points.

For example, the density may lie in the range from one active element 93 per 100 micromirrors through 1 active element 93 per micromirror to 4 or more active elements 93 per micromirror.

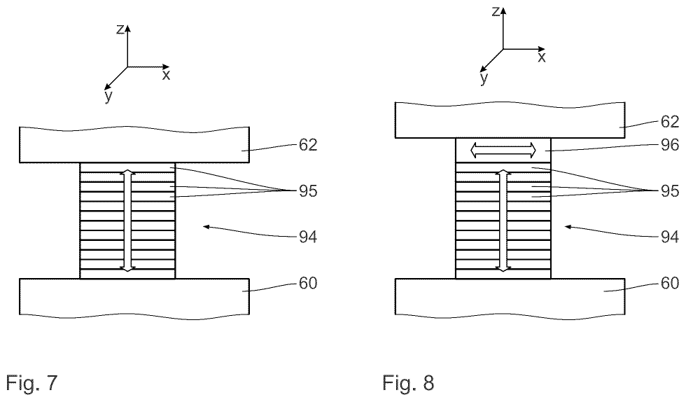

In the case of a realization of the active elements 93 via piezo actuators, it is for example possible to use a multilayer layer stack 94 made of piezoelectrically active layers 95. This is illustrated in FIG. 7 by way of example.

According to the variant illustrated in FIG. 8, compensation in the xy-plane, i.e. parallel to the surface of the plate 62, is also provided in addition to the compensation in the z-direction, i.e. perpendicular to the surface of the plate 62. A passive decoupling element, for example in the form of a suitable spring structure, may be provided as the xy-decoupling structure 96. The passive decoupling element may be integrated into and/or attached to the active elements 93. With regard to details of the passive decoupling element, reference should be made to DE 10 2022 209 935.4.

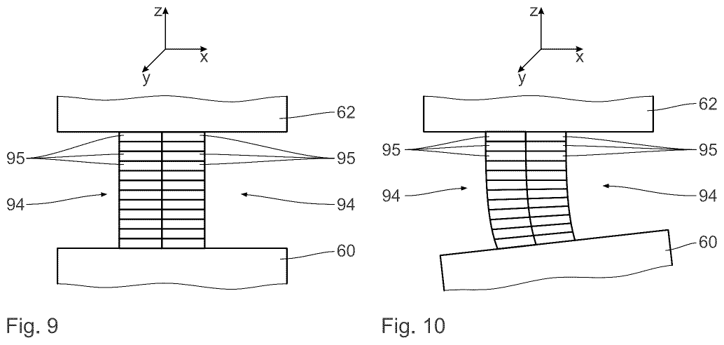

A single active element 93 may be realized by two, three, four or more layer stacks 94. This is illustrated by way of example in FIG. 9. The layer stacks 94 may be connected to one another. They may be arranged symmetrically, for example. For example, it is possible to realize the active element 93 via four symmetrically arranged layer stacks 94 that are connected to one another, for example as are used in piezo stepper motors. In this case, a single active element 93 may potentially provide even better compensation of deformations 92 at the interface 91. For example, in addition to the application of a z-force, it is also possible to directly compensate for a different orientation of the upper side of the load-bearing structure 60 with respect to the lower side of the base plate 62. This is illustrated in FIG. 10 by way of example.

The compensation of the thermal deformations 92 may be effected using a regulated or an unregulated system.

In the case of an unregulated system, the forces may be determined on the basis of a model. With the aid of such a model, the thermal deformations 92 to be expected may be determined on the basis of the incident radiant power and/or the radiant power distribution.

The forces that are used for compensating the expected thermal deformations 92 may be ascertained with the aid of the model.

With the aid of the model, it is also possible to ascertain the control voltages for the active elements 93, by which the desired forces can be generated, and include calculations and/or simulations and/or vibration measurements in the model.

More precise compensation of the thermal deformations 92 is possible using a regulated system. For this purpose, the bearing device may comprise sensors 97. The sensors 97 may be connected by way of a data-transmitting connection to the plate 62 and/or the load-bearing structure 60 and/or one or more of the active elements 93. They may also acquire current state variables of the individual mirrors 20 and/or of the plate 62 and/or of the load-bearing structure 60. For example, the state variables may be temperatures, distances or expansions.

The sensors 97 may be arranged at different locations in the system.

For example, the extension of the components that adjoin the interface 91 may be measured directly with the aid of strain gauges.

The curvature and/or deflection of the components in the region of the interface 91 may be measured with the aid of distance sensors. Provision may also be made for measuring the temperature of the reflection surfaces of the individual mirrors 20 or of other components, for example of elements that are arranged in the region of the interface 91.

A model may in turn be provided for converting the data acquired by sensor means into the desired compensation forces.

A combination of the acquisition of different ones of the aforementioned state variables is also conceivable.

What is claimed is:

1. An optical assembly, comprising:
an optical component;
a load-bearing structure; and
a bearing device mounting the optical component on the load-bearing device,
wherein the bearing device comprises an active element configured to at least partially compensate deformations of the load-bearing structure.

2. The optical assembly of claim 1, comprising a multiplicity of optical components, wherein the multiplicity of optical components comprises mirror elements, and the mirror elements jointly define a mirror group.

3. The optical assembly of claim 1, wherein the optical component comprises a MEMS optical component.

4. The optical assembly of claim 1, further comprising an actuator comprising MEMS actuator elements, wherein the optical component is pivotable via the actuator.

5. The optical assembly of claim 1, wherein the bearing device comprises a base plate between the load-bearing structure and the optical component.

6. The optical assembly of claim 5, wherein at least some of the active element is on a side of the base plate opposite the optical components.

7. The optical assembly of claim 5, further comprising decoupling elements connecting at least a subset of the active element to the base plate.

8. The optical assembly of claim 1, wherein the active element comprises a piezo-actuators or a capacitive actuator.

9. The optical assembly of claim 1, wherein the bearing device comprises a multiplicity of active elements configured to at least partially compensate deformations of the load-bearing structure, and at least a subset of the active elements comprises a multiplicity of piezo actuators.

10. The optical assembly of claim 1, wherein the bearing device comprises a multiplicity of active elements configured to at least partially compensate deformations of the load-bearing structure, and at least a subset of the active elements comprises at least one piezo stack.

11. The optical assembly of claim 1, comprising a multiplicity of optical components, wherein the bearing device comprises a multiplicity of active elements configured to at least partially compensate deformations of the load-bearing structure, and each optical component is assigned to one or more active elements.

12. The optical assembly of claim 1, comprising a multiplicity of optical components, wherein the bearing device comprises a multiplicity of active elements configured to at least partially compensate deformations of the load-bearing structure, and each active element is assigned to a group of optical components.

13. The optical assembly of claim 1, comprising a feedback control system, wherein the bearing device comprises a multiplicity of active elements configured to at least partially compensate deformations of the load-bearing structure, and the active elements define a part of the feedback control system.

14. The optical assembly of claim 1, comprising a pure feed-forward system, wherein the bearing device comprises a multiplicity of active elements configured to at least partially compensate deformations of the load-bearing structure, and the active elements define a constituent part of the pure feed-forward system.

15. The optical assembly of claim 1, comprising a multiplicity of optical components, wherein the optical components comprise MEMS optical components.

16. The optical assembly of claim 1, comprising a multiplicity of optical components and a multiplicity of actuators, wherein each actuator comprises MEMS actuator elements, and each optical component is pivotable via a corresponding actuator.

17. The optical assembly of claim 1, comprising a multiplicity of optical components, wherein the bearing device comprises a base plate between the load-bearing structure and the multiplicity of optical components.

18. A unit, comprising:
an optical assembly according to claim 1,
wherein the unit is an illumination optics unit or a projection optics unit.

19. An apparatus, comprising:
an illumination optics unit; and
a projection optics unit,
wherein:
the apparatus is a microlithographic projection exposure apparatus; and
the illumination optics unit and/or the projection optics unit comprises an optical assembly according to claim 1.

20. A method of using a microlithographic projection exposure apparatus comprising an illumination optics unit and a projection optics unit, the method comprising:
using the illumination optics unit to illuminate an object in an object field of the projection optics unit; and
using the projection optics unit to project the illuminated object into an image field of the projection optics unit,
wherein the illumination optics unit and/or the projection optics units comprises an optical assembly according to claim 1.
